(19) United States
(12) Patent Application Publication
(10) Pub. No.: US 2006/0078025 A1
(43) Pub. Date: Apr. 13, 2006

(54) Ridge waveguide semiconductor laser and method of manufacturing the same

(75) Inventor: Shuji Itonaga, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/181,977

(22) Filed: Jul. 15, 2005

(30) Foreign Application Priority Data
Sep. 30, 2004 (JP) 2004-286371
May 13, 2005 (JP) 2005-140823

(51) Int. Cl. H01S 5/00

(52) U.S. Cl. 372/46.01; 372/45.01

(57) ABSTRACT

A substrate, a laminated structure formed above the substrate and including a first cladding layer, an active layer, and a second cladding layer each containing a compound semiconductor, a current confinement layer containing a compound semiconductor, which is formed on the second cladding layer so as to have an opening, and a ridge portion containing a compound semiconductor, covering the opening of the current confinement layer, and electrically connecting to the second cladding layer, are provided. At least an edge portion of the current confinement layer facing the opening is located under the ridge portion.

### CROSS-REFERENCE TO RELATED APPLICATION

This application is based upon and claims the benefit of priority from prior Japanese Patent Application Nos. 2004-286371, and 2005-140823 filed on Sep. 30, 2004, and May 13, 2005 in Japan, the entire contents of which are incorporated herein by reference.

### BACKGROUND OF THE INVENTION

1. Field of the Invention

The present invention relates to a ridge waveguide semiconductor laser and a method of manufacturing the same.

2. Background Art

A ridge waveguide semiconductor laser does not include any semiconductor embedded layer serving as a current prevention layer, which can be found in many refractive index waveguide structures. Accordingly, a ridge waveguide semiconductor laser has the advantages that no current leakage or reverse junction breakdown occurs in an embedded layer, and no parasitic capacitance is induced from an embedded layer junction, thereby decreasing the parasitic capacitance of the entire device.

Although a ridge waveguide semiconductor laser has great advantages, a high controllability is required to form a ridge structure thereof.

A method is known for forming a ridge portion using RIE (Reactive Ion Etching). In this method, first, a first cladding layer, an active layer, a second cladding layer, an etching stopper layer, a third cladding layer, and a contact layer are sequentially formed on a substrate of n-type GaAs. The etching stopper layer and the third cladding layer are formed of materials each having a different etching selectivity. Subsequently, a silicon oxide layer serving as a mask at the time of forming a ridge portion on the contact layer and a resist pattern are formed. Thereafter, the resist pattern is transferred to the silicon oxide layer using RIE, thereby forming a silicon oxide layer pattern. After the resist pattern is removed, the contact layer and the third cladding layer are etched by RIE using the silicon oxide layer pattern as a mask. The etching by RIE is stopped immediately before the etching stopper layer is exposed. In this way, the third cladding layer is divided into a thick portion immediately below the silicon oxide layer pattern serving as the ridge portion, and a thin portion left on the etching stopper layer. Next, the thin third cladding layer left on the etching stopper layer is etched by a wet etching, thereby exposing the etching stopper layer. Thereafter, the silicon oxide layer pattern serving as a mask and the exposed etching stopper layer are removed, thereby forming a ridge portion composed of the etching stopper layer, the third cladding layer, and the contact layer on the second cladding layer formed on the active layer. The etching stopper layer is used to control the height of the ridge portion with a high accuracy.

In the ridge waveguide semiconductor laser formed by this manufacturing method, an etching stopper layer is formed on a bottom portion of the ridge portion. Since the resistance of the etching stopper layer is generally higher than that of the third cladding layer, there is a problem in that the operating voltage of the ridge waveguide semiconductor laser becomes higher.

A few methods are known to use a selective epitaxial growth technique to form a ridge portion, as disclosed in, for example, Japanese Patent Laid-Open Publication Nos. 97510/1996, 2000-29487, and 2000-312053. In this technique, a first cladding layer, an active layer, and a second cladding layer are first sequentially formed on a substrate. Then, a layer such as an insulating layer or a protection layer (dielectric layer) formed of a material unlikely to allow an epitaxial growth, e.g., a silicon oxide, is formed on the second cladding layer, and a mask having an opening only in a region where a ridge portion is to be formed is formed by patterning this layer. Thereafter, a selective epitaxial growth is performed on the second cladding layer at the bottom of the opening portion using the mask, thereby forming a ridge portion. Although there is no need of forming an etching stopper layer that has a high resistance in this technique, it is necessary to form a ridge portion by a selective epitaxial growth. Since the ridge growth direction has crystal orientation dependence, the ridge shape controllability of this technique is lower than that of a method of forming a ridge portion using RIE. Accordingly, it is difficult to form a desired ridge shape.

### SUMMARY OF THE INVENTION

A ridge waveguide semiconductor laser according to a first aspect of the present invention includes:

a substrate;

a laminated structure formed above the substrate and including a first cladding layer, an active layer, and a second cladding layer each containing a compound semiconductor;

a current confinement layer containing a compound semiconductor, which is formed on the second cladding layer so as to have an opening; and

a ridge portion containing a compound semiconductor, covering the opening of the current confinement layer, and electrically connecting to the second cladding layer,

at least an edge portion of the current confinement layer which faces the opening being located under the ridge portion.

A ridge waveguide semiconductor laser according to a second aspect of the present invention includes:

a substrate;

a laminated structure formed above the substrate and including a first cladding layer, an active layer, and a second cladding layer;

a current confinement layer formed on the second cladding layer so as to have an opening;

a ridge portion covering the opening of the current confinement layer and electrically connecting to the second cladding layer; and

a dummy ridge portion provided on the current confinement layer so as to have a predetermined space between the ridge portion and the dummy ridge portion,

at least an edge portion of the current confinement layer facing the opening being located under the ridge portion.

A method of manufacturing a ridge waveguide semiconductor laser according to a third aspect of the present invention includes:

sequentially forming a first cladding layer, an active layer, and a second cladding layer above a substrate;

forming an etching stopper layer on the second cladding layer;

patterning the etching stopper layer to form an opening through the etching stopper layer;

forming a third cladding layer covering the etching stopper layer and the opening;

forming a contact layer on the third cladding layer; and

forming a mask used to form a ridge portion on the contact layer above the opening of the etching stopper layer, and etching the contact layer and the third cladding layer using the mask to form the ridge portion.

### BRIEF DESCRIPTION OF THE DRAWINGS

FIG. 1 is a sectional view for explaining the structure of a ridge waveguide semiconductor laser according to a first embodiment of the present invention.

FIGS. 2A to 2D are sectional views showing steps for manufacturing the ridge waveguide semiconductor laser of the first embodiment.

FIGS. 3A to 3D are sectional views showing steps for manufacturing the ridge waveguide semiconductor laser of the first embodiment.

FIG. 4 is a sectional view showing the structure of a ridge waveguide semiconductor laser according to a first modification of the first embodiment.

FIG. 5 is a sectional view showing the structure of a ridge waveguide semiconductor laser according to a second modification of the first embodiment.

FIG. 6 is a sectional view showing the structure of a ridge waveguide semiconductor laser according to a second embodiment of the present invention.

FIGS. 7A and 7B are sectional views showing steps for manufacturing the ridge waveguide semiconductor laser according to the second embodiment.

FIG. 8 is a sectional view showing the structure of a ridge waveguide semiconductor laser according to a modification of the second embodiment.

FIG. 9 is a sectional view showing the structure of a ridge waveguide semiconductor laser according to a third embodiment of the present invention.

### DESCRIPTION OF THE EMBODIMENTS

Hereinafter, embodiments of the present invention will be described in detail with reference to the accompanying drawings.

### First Embodiment

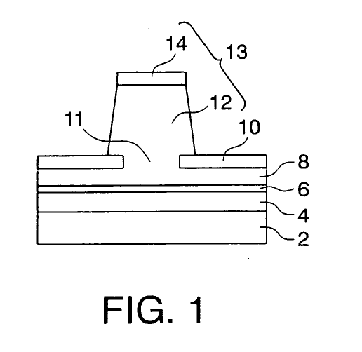

FIG. 1 is a sectional view for explaining the structure of a ridge waveguide semiconductor laser according to a first embodiment of the present invention. The ridge waveguide semiconductor laser of this embodiment includes a laminated structure provided on a substrate 2 of, e.g., n-type GaAs, having a double-hetero junction and including a first cladding layer 4 of, e.g., n-type InGaAlP, an active layer 6 of, e.g., InGaAlP type, having a multi-quantum well structure, and a second cladding layer 8 of, e.g., p-type InGaAlP, a current confinement layer 10 of a compound semiconductor formed on the second cladding layer 8 and having an opening 11, and a ridge portion 13 formed by stacking a third cladding layer 12 of, e.g., p-type InGaAlP and a contact layer 14 formed on the third cladding layer 12, the third cladding layer 12 covering the opening 11 of the current confinement layer 10 and electrically connected to the second cladding layer 8 via the opening 11 of the current confinement layer 10. In this embodiment, an edge portion of the current confinement layer 10 at the opening 11 side is located under the ridge portion 13.

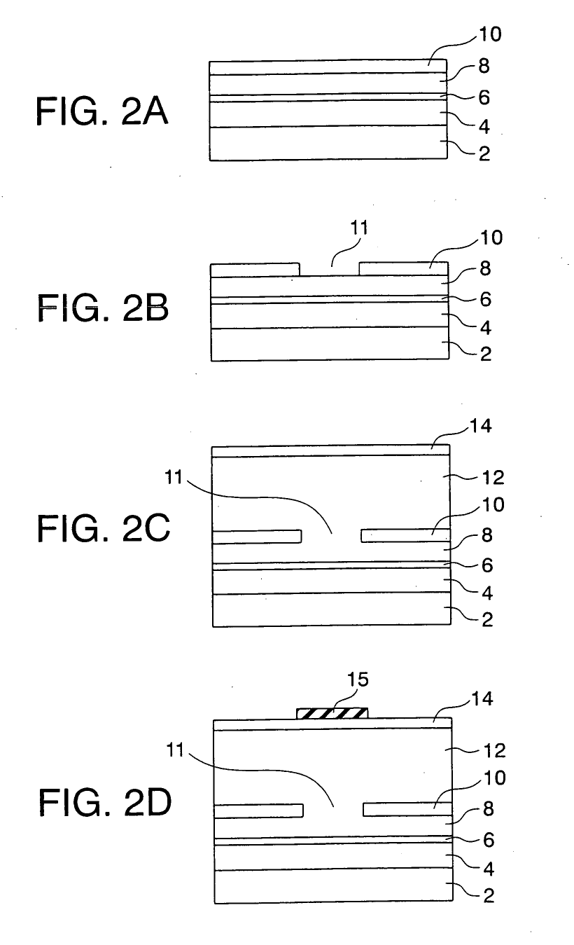

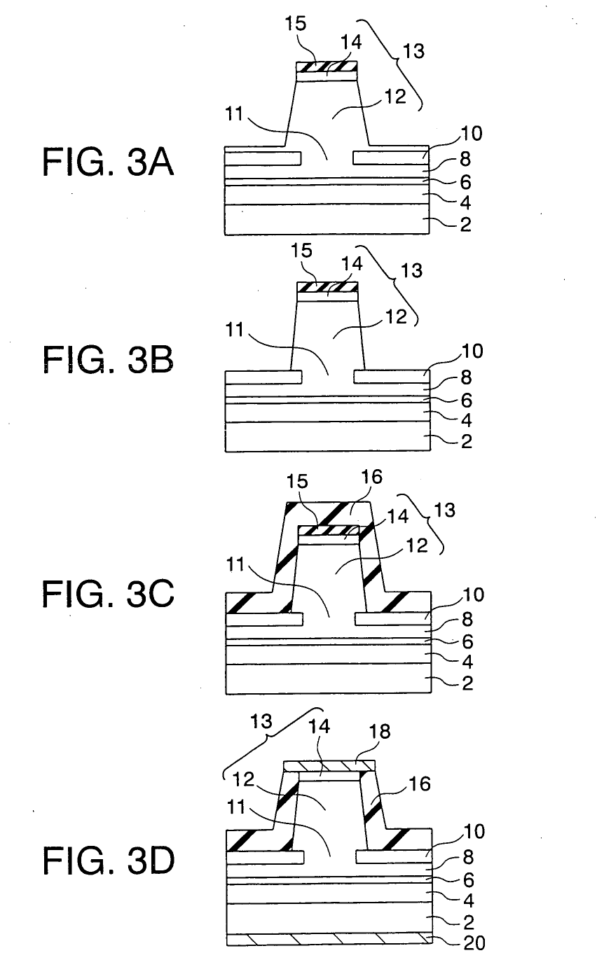

Next, a method of manufacturing a ridge waveguide semiconductor laser according to this embodiment will be described with reference to FIG. 2 A to FIG. 3D, which are sectional views showing steps for manufacturing a ridge waveguide semiconductor laser according to this embodiment.

First, a first cladding layer 4 of n-type InGaAlP, an active layer 6 of InGaAlp type having a multi-quantum well structure, a second cladding layer 8 of p-type InGaAlP, and a layer 10 of, e.g., p-type InGaP, are sequentially formed on a substrate 2 of n-type GaAs by an epitaxial growth (FIG. 2A). Thereafter, an opening 11 is formed by patterning the layer 10 of p-type InGaP (FIG. 2B). At this time, the second cladding layer 8 is exposed at the bottom of the opening 11. With the opening 11, an electric current can intensively flow through the opening 11, i.e., the layer 10 works to confine the electric current and serves as a current confinement layer.

Next, a third cladding layer 12 of p-type InGaAlP is epitaxially grown, and then a contact layer 14 of, e.g., p-type GaAs, is formed on the third cladding layer 12 (FIG. 2C). In this manner, the third cladding layer 12 is formed not only on the second cladding layer 8 exposed at the bottom of the opening 11, but also on the current confinement layer 10. Unlike a conventional technique using selective epitaxial growth, the current confinement layer 10 in this embodiment is formed of a compound semiconductor (p-type InGaP in this embodiment). Accordingly, a compound semiconductor (p-type InGaP in this embodiment) having a good crystallinity is formed not only at the bottom portion of the opening 11 but also on the current confinement layer 10. As a result, the problem of crystal defect in the third cladding layer, which is likely to occur when a compound semiconductor is grown by selective epitaxial growth from the bottom of the opening 11 to above the edge portion of the current confinement layer 10 composed of an insulating film or a dielectric film, hardly occurs in this embodiment, thereby curbing the occurrence of a leakage current.

Then, a silicon oxide layer pattern 15 of a photoresist is formed on the contact layer 14 directly above the opening 11 of the current confinement layer 10 (FIG. 2D). Specifically, a silicon oxide layer is formed on the contact layer 14, a resist pattern of photoresist is formed on the silicon oxide layer, the resist pattern is transferred to the silicon oxide layer by RIE to form the silicon oxide layer pattern 15, and then the resist pattern is removed. In this embodiment, the size of the silicon oxide layer pattern 15 is determined to be larger than that of the opening 11 of the current confinement layer 10.

Thereafter, the contact layer 14 and the third cladding layer 12 are etched by RIE (Reactive Ion Etching) using the silicon oxide layer pattern 15 as a mask to form a ridge portion 13 (FIG. 3A). The etching using RIE is stopped immediately before the current confinement layer 10 is exposed, thereby leaving a thin p-type InGaAlP layer 12 on the current confinement layer 10, as shown in FIG. 3A.

Then, the thin p-type InGaAlP layer 12 left on the current confinement layer 10 is removed by wet etching using, e.g., phosphoric acid, thereby exposing the current confinement layer 10 (FIG. 3B). Since the current confinement layer 10 is formed of p-type InGaP, the etching selectivity of the InGaAlP layer 12 is higher relative to the layer 10 formed of p-type InGaP. Accordingly, the current confinement layer 10 is hardly etched. In other words, the current confinement layer 10 serves as an etching stopper layer at the time of wet etching. Furthermore, since the side portion of the ridge portion 13 has a different plane orientation, the side portion is hardly etched. Accordingly, the ridge portion 13 having a bottom area larger than the area of the opening 11 of the current confinement layer 10 is ultimately formed. In order to improve the shape controllability of the ridge portion 13 further, a sidewall composed of a silicon oxide layer may be formed at the side portion of the ridge portion 13 before the wet etching.

As described above, the material of the current confinement layer 10 have a function of etching stopper, with which it is possible to pattern the third cladding layer 12 with a high etching selectivity. When the third cladding layer 12 is formed of InGaAlP, the material of the current confinement layer 10 can be p-type InGaP, as described above, undoped InGaP, or n-type InGaP. Furthermore, when phosphoric acid is used in wet etching, the material of the current confinement layer 10 can be undoped GaAs or n-type GaAs which are hardly etched by phosphoric acid.

Subsequently, a current block layer 16 of, e.g., silicon oxide, is formed so as to cover the ridge portion 13 and the current confinement layer 10 (FIG. 3C).

Then, polyimide (not shown in the drawings) is deposited to cover the current block layer 16. Subsequently, the polyimide is etched back using oxygen gas, thereby exposing the current block layer 16 on the contact layer 14. Thereafter, the current block layer 16 and the silicon oxide layer pattern 15 serving as the mask above the contact layer 14 are removed using a photolithography technique, thereby exposing the contact layer 14. Then, an upper electrode 18 connecting to the contact layer 14 and a lower electrode 20 connecting to the substrate 2 are formed, the lower electrode 20 being at a surface opposite to the side where there is the first cladding layer 4 (FIG. 3D). Thereafter, the polyimide is removed to complete the ridge waveguide semiconductor laser.

In the ridge waveguide semiconductor laser of this embodiment thus manufactured, when a current flows between the upper electrode 18 and the lower electrode 20, light emitted from the active layer 6 is outputted in a direction perpendicular to the paper surface of FIG. 3D.

As described above, according to this embodiment, unlike conventional devices, since the etching stopper layer is not formed on the entire bottom surface of the ridge portion 13, it is possible to prevent the operating voltage of the semiconductor laser from increasing.

Furthermore, since most of the ridge portion 13 is formed by dry etching, it is possible to achieve a predetermined shape.

Moreover, since the edge portion of the current confinement layer 10 facing the opening 11 is placed below the ridge portion 13, it is possible to allow a current to flow intensively through the center portion of the ridge portion 13. Furthermore, a crystal defect is hardly generated in the third cladding layer 12 even on the edge portion of the current confinement layer 10. Accordingly, a higher output can be achieved.

In this embodiment, when n-type InGaP or n-type GaAs is used to form the current confinement layer 10, a reverse bias is constituted with respect to the second cladding layer 8 formed of p-type InGaAlP, thereby increasing the resistance. Accordingly, it is possible to curb the current flowing through the edge portion of the ridge portion 13 further, thereby achieving a still higher output.

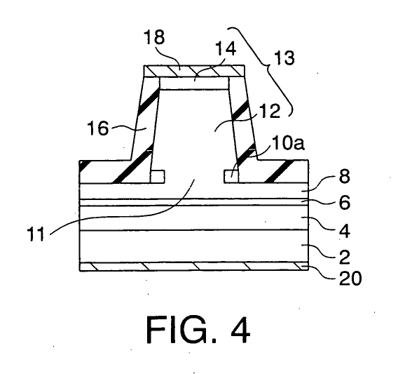

In this embodiment, the current confinement layer 10 is formed on the second cladding layer 8 at the side of the ridge portion 13. However, as shown in FIG. 4, the current confinement layer 10 can be removed so as to selectively form a current confinement layer 10a at the lower portion of the ridge portion 13 but not at the portion at the side of the ridge portion 13 on the second cladding layer 8. In this manner, it is also possible to prevent the operating voltage of the semiconductor laser from increasing, and to achieve a higher output.

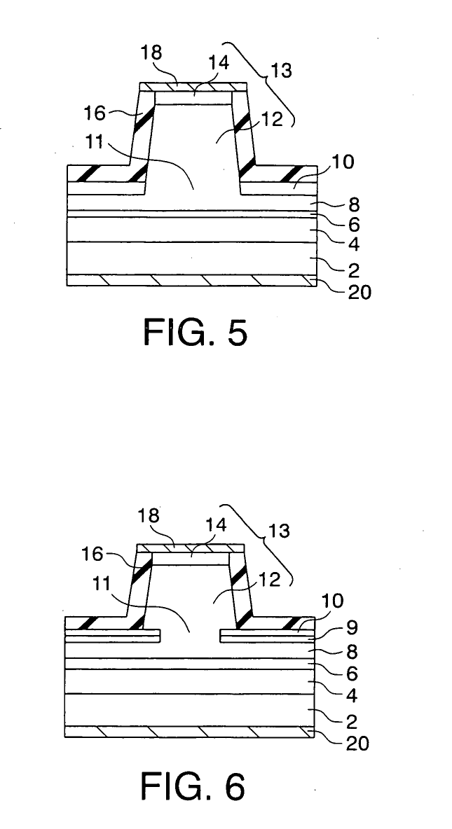

Also in this embodiment, it is possible to form the ridge portion 13 so as to have a bottom area that is equivalent in size to the opening 11 of the confinement layer 10 by appropriately selecting the size of the silicon oxide layer pattern 15 used to form the ridge portion 13, e.g., by selecting substantially the same size as the size of the opening 11 of the current confinement layer 10, thereby preventing an edge portion of the current confinement layer 10 facing the opening 11 from being located under the ridge portion 13, as shown in FIG. 5. Also in this case, it is possible to prevent the operating voltage of the semiconductor laser from increasing.

### Second Embodiment

Next, a ridge waveguide semiconductor laser according to a second embodiment of the present invention will be described with reference to FIG. 6, which is a sectional view showing the structure of the ridge waveguide semiconductor laser of this embodiment.

In the first embodiment, a single layer formed of InGaP is used as the current confinement layer 10. However, in a ridge waveguide semiconductor laser of this embodiment, a stacked layer composed of a layer 10 of InGaP and a layer 9 of InAlP, which has a higher resistance than InGaP, is used as the current confinement layer. Since the layer 9 of InAlP is unlikely to have a higher etching selectivity with respect to the third cladding layer 12 than the layer 10 of InGaP, the layer 9 is formed at the side of the second cladding layer 8. In addition, the InGaP layer 10 and the InAlP layer 9 have a common opening 11.

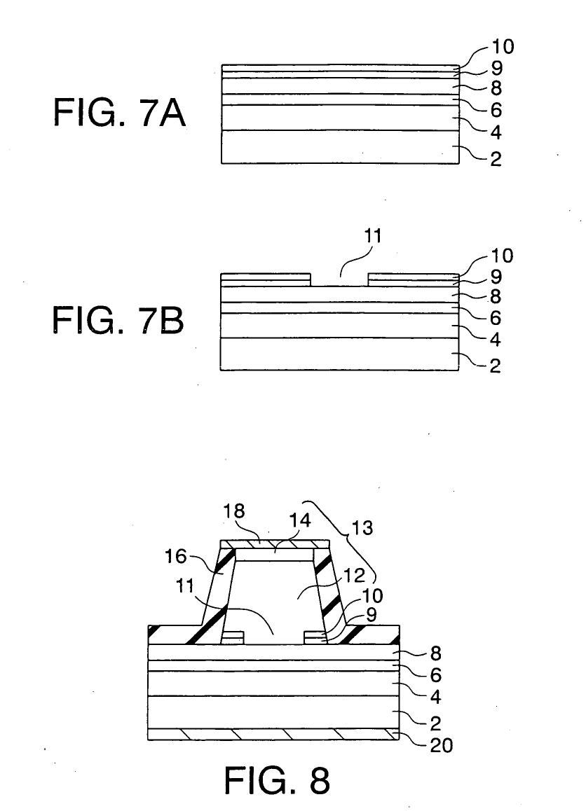

The ridge waveguide semiconductor laser according to this embodiment is manufactured by sequentially forming a first cladding layer 4, an active layer 6, a second cladding layer 8, an InAlP layer 9, and an InGaP layer 10 on a substrate 2 by epitaxial growth, as shown in FIG. 7A. Thereafter, the InGaP layer 10 and the InAlP layer 9 are patterned to form a common opening 11 therethrough, as shown in FIG. 7B. The rest of the manufacturing steps are the same as those shown in FIG. 2C and the following drawings of the first embodiment.

As in the case of the first embodiment, when the third cladding layer 12 is formed of InGaAlP, the material of the current confinement layer 10 can be undoped InGaP, p-type InGaP, or n-type InGaP. Furthermore, when phosphoric acid is used in wet etching, the material of the current confinement layer 10 can be undoped GaAs or n-type GaAs which are hardly etched by phosphoric acid.

Since the stacked layer composed of the layer 10 of InGaP and the layer 9 of InAlP, which has a higher resistance than InGaP, is used as the current confinement layer in this embodiment, it is possible to further curb a current flowing through the edge portion of the ridge portion 13 as compared to the first embodiment, thereby achieving a still higher output.

Of course, like the first embodiment, it is possible to prevent the operating voltage of the semiconductor laser from increasing, and to form a desired ridge shape. Further, it is possible to curb the occurrence of a leakage current since a crystal defect is hardly generated in the third cladding layer 12.

Although the InGaP layer 10 and the InAlP layer 9 of this embodiment serving as the current confinement layer are formed also on the second cladding layer 8 at the side of the ridge portion 13, it is also possible to prevent the operating voltage of the semiconductor laser from increasing by not forming the InGaP layer 10 and the InAlP layer 9 on the second cladding layer 8 at the side of the ridge portion 13, but selectively forming them under the ridge portion 13, as shown in FIG. 8, thereby achieving a higher output. Furthermore, when the resistance of the InAlP layer 9 is sufficiently high in this embodiment it is possible to omit the formation of the current block layer 16 shown in FIGS. 6 and 8.

### Third Embodiment

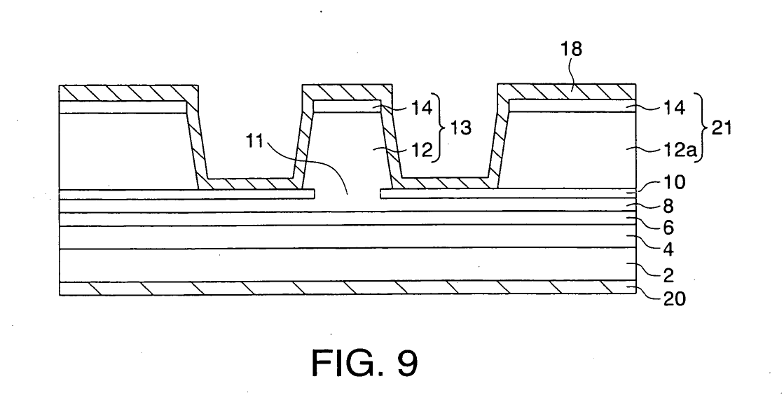

Next, a ridge waveguide semiconductor laser according to a third embodiment of the present invention will be described with reference to FIG. 9, which is a sectional view showing the structure of the ridge waveguide semiconductor laser of this embodiment.

The ridge waveguide semiconductor laser according to this embodiment has a structure in which the current block layer 16 is removed from the ridge waveguide semiconductor laser of the first embodiment shown in FIG. 3D and a dummy ridge portion 21, which is located away from the ridge portion 13 with a predetermined space left therebetween. The dummy ridge portion 21 includes a p-type InGaAlP layer 12a formed by epitaxial growth on the current confinement layer 10 of a compound semiconductor, and a contact layer 14 of, e.g., p-type GaAs, formed on the InGaAlP layer 12a. The p-type InGaAlP layer 12a is formed at the same time as the third cladding layer 12 of the ridge portion 13.

With the dummy ridge portion 21 of this embodiment, it is possible to decrease the impact on or the damage to the ridge portion 13 during the period after the ridge portion 13 is formed and before the completion of the formation of the upper electrode 18 and the implementation of the device on the implementation part, as compared to the case where only the ridge portion 13 projects from the surface of the device as in the case of the first embodiment.

Furthermore, with the dummy ridge portion 21, the heat releasing property of the ridge waveguide semiconductor laser producing a higher output is improved, thereby preventing the degradation of the device characteristics.

In this embodiment, the current confinement layer 10 of a compound semiconductor has an opening only at the ridge portion 13. Accordingly, it is possible not to form the current block layer 16 shown in FIG. 3D at the side portion of the ridge portion 13 and on the dummy ridge portion 21 when the current confinement layer 10 has a high resistance. Specifically, a stacked layer composed of a layer 9 of InAlP and a layer 10 of the second embodiment, or a layer of n-type InGaP or n-type GaAs, which constitutes a reverse bias with respect to the second cladding layer 8, can be used as the current confinement layer 10 with high resistance in this embodiment.

Like the first embodiment, in the third embodiment, it is possible to prevent the operating voltage of the semiconductor laser from increasing, and to form a desired ridge shape. Further, it is possible to curb the occurrence of a leakage current since a crystal defect is hardly generated in the third cladding layer 12.

According to the embodiments of the present invention, it is possible to have a ridge waveguide semiconductor laser which can prevent the operating voltage from increasing and in which a ridge portion having a desired shape can be formed, and a method of manufacturing the same.

The ridge waveguide semiconductor laser according to any one of the embodiments of the present invention can be applied to a gallium nitride system composed of a compound semiconductor containing any one of GaN, InGaN, InGaAlN etc. In this case, the current confinement layer (the etching stopper layer) can be formed of for example AlN.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

1. A ridge waveguide semiconductor laser comprising:
a substrate;
a laminated structure formed above the substrate and including a first cladding layer, an active layer, and a second cladding layer each containing a compound semiconductor;
a current confinement layer containing a compound semiconductor, which is formed on the second cladding layer so as to have an opening; and
a ridge portion containing a compound semiconductor, covering the opening of the current confinement layer, and electrically connecting to the second cladding layer,
at least an edge portion of the current confinement layer which faces the opening being located under the ridge portion.

2. The ridge waveguide semiconductor laser according to claim 1, wherein the ridge portion includes a third cladding layer covering the opening of the current confinement layer, and a contact layer formed on the third cladding layer.

3. The ridge waveguide semiconductor laser according to claim 2, wherein the third cladding layer is formed of InGaAlP, and the current confinement layer is formed of one material selected from InGaP and GaAs.

4. The ridge waveguide semiconductor laser according to claim 1, wherein the second cladding layer is formed of a first semiconductor layer of a first conductivity type, and the current confinement layer is formed of a second semiconductor layer of a second conductivity type.

5. The ridge waveguide semiconductor laser according to claim 1, wherein the current confinement layer having the opening is selectively located under the ridge portion.

6. The ridge waveguide semiconductor laser according to claim 1, wherein the current confinement layer includes a first current confinement film and a second current confinement film provided between the second cladding layer and the first current confinement film and formed of a material having a higher resistance than a material of the first current confinement film.

7. The ridge waveguide semiconductor laser according to claim 6, wherein the first current confinement film is formed of InGaP and the second current confinement film is formed of InAlP.

8. The ridge waveguide semiconductor laser according to claim 2, further comprising a current block layer covering a side portion of the ridge portion and the current confinement layer or the second cladding layer, a first electrode connecting to the contact layer and a second electrode connecting to a surface of the substrate opposite to a side where the first cladding layer is provided.

9. A ridge waveguide semiconductor laser comprising:
a substrate;
a laminated structure formed above the substrate and including a first cladding layer, an active layer, and a second cladding layer;
a current confinement layer formed on the second cladding layer so as to have an opening;
a ridge portion covering the opening of the current confinement layer and electrically connecting to the second cladding layer; and
a dummy ridge portion provided on the current confinement layer so as to have a predetermined space between the ridge portion and the dummy ridge portion,
at least an edge portion of the current confinement layer which faces the opening being located under the ridge portion.

10. A method of manufacturing a ridge waveguide semiconductor laser comprising:
sequentially forming a first cladding layer, an active layer, and a second cladding layer above a substrate;
forming an etching stopper layer on the second cladding layer;
patterning the etching stopper layer to form an opening through the etching stopper layer;
forming a third cladding layer covering the etching stopper layer and the opening;
forming a contact layer on the third cladding layer; and
forming a mask used to form a ridge portion on the contact layer above the opening of the etching stopper layer, and etching the contact layer and the third cladding layer using the mask to form the ridge portion.

11. The method of manufacturing a ridge waveguide semiconductor laser according to claim 10, wherein the ridge portion has a bottom area larger than the opening of the etching stopper layer.

12. The method of manufacturing a ridge waveguide semiconductor laser according to claim 10, wherein the ridge portion has a bottom area which is substantially the same in size as the opening of the etching stopper layer.

13. The method of manufacturing a ridge waveguide semiconductor laser according to claim 10, wherein the forming of the ridge portion includes:
etching the contact layer and subsequently the third cladding layer by RIE using the mask, the etching of the third cladding layer being terminated immediately before the etching stopper layer is exposed; and
removing the third cladding layer left on the etching stopper layer by wet etching.

14. The method of manufacturing a ridge waveguide semiconductor laser according to claim 10, wherein the second cladding layer is formed of a first semiconductor layer of a first conductivity type, and the etching stopper layer is formed of a second semiconductor layer of a second conductivity type.

15. The method of manufacturing a ridge waveguide semiconductor laser according to claim 10, further comprising:
etching and removing the etching stopper layer at a side portion of the ridge portion.

16. The method of manufacturing a ridge waveguide semiconductor laser according to claim 10, wherein each of the first cladding layer, the active layer, the second cladding layer, the etching stopper layer, and the third cladding layer is formed of a compound semiconductor.

17. The method of manufacturing a ridge waveguide semiconductor laser according to claim 10, wherein the etching stopper layer includes a first etching stopper film and a second etching stopper film formed between the second cladding layer and the first etching stopper film, the second etching stopper film having a resistance higher than a resistance of the first etching stopper film and the first and second etching stopper films having a common opening formed in the forming of the opening through the etching stopper layer.

18. The method of manufacturing a ridge waveguide semiconductor laser according to claim 17, wherein etching selectivity of the third cladding layer with respect to the first etching stopper film is higher than that with respect to the second etching stopper film.

19. The method of manufacturing a ridge waveguide semiconductor laser according to claim 18, wherein the first etching stopper film is formed of InGaP and the second etching stopper film is formed of InAlP.

20. The method of manufacturing a ridge waveguide semiconductor laser according to claim 10, further comprising:
forming a current block layer covering the ridge portion and the etching stopper layer or the second cladding layer;
removing the current block layer on the contact layer so as to expose the contact layer; and
forming a first electrode connecting to the contact layer and a second electrode connecting to a surface of the substrate opposite to a side where the first cladding layer is provided.
